(19) United States
(12) Patent Application Publication
(10) Pub. No.: US 2017/0288369 A1
(43) Pub. Date: Oct. 5, 2017

(54) DUAL CLOSED LOOP FOR LASER POWER CONTROL

(71) Applicant: MACOM Technology Solutions Holdings, Inc., Lowell, MA (US)

(72) Inventors: Quazi Ikram, Irvine, CA (US); Cristiano Bazzani, Irvine, CA (US)

(21) Appl. No.: 15/477,956

(22) Filed: Apr. 3, 2017

Related U.S. Application Data
(60) Provisional application No. 62/317,308, filed on Apr. 1, 2016.

(51) Int. Cl. H01S 5/042; H04B 10/564; H04B 10/50; H01S 5/0683

(52) U.S. Cl. CPC H01S 5/0427; H01S 5/0683; H04B 10/564; H04B 10/503

(57) ABSTRACT

A power control system comprising a laser driver that receives a data signal, and responsive to a modulation control signal and a bias control signal, processes the data signal to drive a laser to generate an optic signal that represents the data signal. A monitor photodiode configured to receive the optic signal and generate a monitor photodiode signal.

A modulation control path, that processes a monitor photodiode signal and a reference signal, including at least one filter and at least one mixer. The modulation control path generates a modulation control signal. A bias control path, that processes the monitor photodiode signal and the reference signal, that includes at least one filter and at least one average weighting module to generate a modulation control signal. The bias control path and the modulation control path processing reduces the effect of the error in the monitor photodiode signal.

### 1. PRIORITY CLAIM

This application claims priority to and the benefit of U.S. Provisional Patent Application 62/317,308 filed on Apr. 1, 2016, the contents of which are incorporated by reference in its entirety herein.

### 2. FIELD OF THE INVENTION

The invention relates to optic signal generation and in particular to a method and apparatus for controlling the power level of an optic signal generator.

### 3. RELATED ART

In an exemplary optical fiber link lasers or some other form of optic signal generator are used as the source of light in the transmitter. FIG. 1 illustrates an exemplary optic fiber communication link. To enable communication between remote networking equipment 104A, 104B a fiber optic transmitter and receiver is provided. Laser drivers 112, part of a transmitter 108, drive the lasers 116 with a modulating current which produces modulating optical output from lasers. This optical output is coupled into the optical fiber 120 for signal transmission. At the receive side of the optical fiber link is a receiver 128. Optical energy is converted into electrical signals by a photodiode 132 and processed further by an amplifier 136 to set the signal magnitude to a level suitable for further processing. However, due to the loss in the optical fiber 120, the optical power received by the receiver 128 is substantially degraded. As a result, it is very critical that the laser 116 maintain its optical power output over various operating conditions and aging.

A laser's optical power vs. current characteristic is strongly dependent on temperature and age. This dependency impacts the performance of the optical link significantly. With change in temperature and/or aging, the laser threshold current Ith and slope efficiency (η) change. FIG. 2A shows current variation over temperature for a laser. As shown, the horizontal axis 204 represents temperature while the vertical axis 208 represents current in milliamps. As can be seen in this plot, as temperature changes so too does threshold current. This is generally undesirable. FIG. 2B shows laser slope efficiency variation over temperature for the same laser. As shown, the horizontal axis 204 represents temperature while the vertical axis 216 represents slope efficiency. Again, the fact that slope efficiency changes over temperature is generally undesirable.

The variations in threshold current and slope efficiency, in turn, modifies the transmitted high (1) level and low (0) levels, as shown in FIG. 3. As shown in the signal plots of FIGS. 3A and 3B, the optical power level of the transmitted signal in FIG. 3A differs from the optical power level of the transmitted signal in FIG. 3B. This may cause decreased link budget and eventually lead to increase in BER. For this reason, some mean of automatic laser power control is required to maintain desired power levels and thus the desired performance of the optical link.

As is understood in the prior art, laser power can be controlled open loop, but a closed loop system is more desirable. In a closed loop system, laser output power is sensed and fed back to the chip. A typical closed loop power control system is shown in FIG. 4. As shown, a data signal 404 is presented to a laser driver 408 that is part of a transmitter 406. The driver generates a laser drive signal suitable for driving a laser 412. The laser 412 received the driver output and generates an optic signal which is presented to an optic fiber. Monitoring the generated optic signal is a monitor photo diode (MPD) 416 which converts the optic signal to a corresponding electrical signal. The electrical output from the MPD 416 is presented to a comparator 420 which compares the MPD output to a reference signal, such as a reference current. The output from the comparator is an error signal indicative of the difference between the optic signal power level and a reference value. An automatic power control module 424 generates a power control signal, which is provide to the laser driver, to adjust the power of the optic signal via the drive signal to compensate for changes in temperature. For example, the APC loop changes laser current to maintain the desired power levels. It is assumed that change in MPD 416 behavior over temperature or aging is much smaller than laser behavior.

### 4. SUMMARY

To overcome the drawbacks of the prior art and provide additional benefits, an optic signal generator power control system is disclosed. In one embodiment, a laser driver is part of the system and is configured to receive and process a data signal, a modulation control signal, and a bias control signal, and process, responsive to the modulation control signal, and a bias control signal such that the data signal is received by an optic signal generator for generation of an optic signal. Also, part of this embodiment is a monitor photodiode configured to receive the optic signal and generate a monitor photodiode signal. The monitor photodiode signal comprises the data signal and errors introduced by the monitor photodiode or other system impairments. A modulation control path is provided and configured to process the monitor photodiode signal, the modulation control path including at least one filter and an average weighting module configured to remove errors in the monitor photodiode signal. A bias control path is configured to process the monitor photodiode signal. The bias control path includes at least one filter and at least one mixer configured to remove errors in the monitor photodiode signal. One or more counters are configured to receive the output of the modulation control path and the bias control path and responsive thereto, generate one or more digital output signal. A modulation digital to analog converter is provided and configured to convert the digital output signal from at least one of the one or more counters to the modulation control signal while a bias digital to analog converter configured to convert the digital output from at least one of the one or more counters to the modulation control signal.

The error in the monitor photodiode consists of one or more the following: overshoot, ringing, and noise. In one embodiment, the modulation control path includes a comparator configured to compare a processed version of the monitor photodiode signal to a reference signal, the reference signal undergoing the same processing as the monitor photodiode signal in the modulation control path. It is contemplated that in this system the bias control path may include a comparator configured to compare a processed version of the monitor photodiode signal to a reference signal, the reference signal undergoing the same processing as the monitor photodiode signal in the bias control path. The modulation control path may include a transimpedance amplifier, a common mode filter, a single ended to differential format module, one or more signal filters, a mixer, a mixer filter, and a comparator. The bias control path may include band-limit filter, an average weighting module, an average power control filter, and a comparator.

In another embodiment, an optic signal generator power control system is disclosed in which a laser driver is configured to receive a data signal, and responsive to a modulation control signal, and a bias control signal, process the data signal to a format suitable for driving an optic signal generator to generate an optic signal that represents the data signal. A monitor photodiode is configured to receive the optic signal and generate a monitor photodiode signal. The monitor photodiode signal comprises the data signal and errors introduced by the monitor photodiode. A modulation control path is also part of the system and is configured to process a monitor photodiode signal and a reference signal. Both the monitor photodiode signal and the reference signal are processed by at least one filter and at least one mixer, both of which are in the modulation control path and are configured to generate a modulation control signal. Also part of this system is a bias control path configured to process the monitor photodiode signal and the reference signal, both the monitor photodiode signal and the reference signal processed by at least one filter and at least one average weighting module that are in the bias control path. The processing generating a modulation control signal, such that the bias control path and the modulation control path reduce or eliminate an effect of the error in the monitor photodiode signal.

In one embodiment, the system further comprises a first transimpedance amplifier configured to process monitor photodiode signal and a second transimpedance amplifier configured to process the reference signal. The system may further comprise one or more counters configured to receive an output of the modulation control path and an output of the bias control path and responsive thereto, generate one or more digital output signal, a modulation digital to analog converter configured to convert the digital output signal from at least one of the one or more counters to the modulation control signal, and a bias digital to analog converter configured to convert the digital output from at least one of the one or more counters to the bias control signal.

In one embodiment of the system, the at least one filter in the modulation control path includes four signal filters and a mixer filter and the at least one mixer in the modulation control path includes a mixer configured to calculate the power of the monitor photodiode signal and a mixer configured to calculate the power of the reference signal. It is contemplated that the bias control path includes band-limit filter, an average weighting module, an average power control filter, and a comparator. In one configuration, the same processing is performed on the monitor photodiode signal and the reference signal

Also disclosed is a method for processing a monitor photodiode signal to remove errors in the monitor photodiode signal as compared to a corresponding data signal. In this example method of operation, the system receives the monitor photodiode signal, and a reference signal. The system processes the monitor photodiode signal and the reference signal with one or more transimpedance amplifiers to generate a monitor photodiode current signal and a reference current signal. Then, this method of operation processes the monitor photodiode current signal and the reference current signal with a modulation control path to generate a modulation current control signal. The modulation control path includes at least one mixer configured to generate the power of the monitor photodiode current signal and the power of the reference current signal. Processing occurs on the monitor photodiode current signal and the reference current signal with a bias control path to generate a bias current control signal. The bias control path includes at least one average weighting module configured to determine an average value for the monitor photodiode current signal and the power of the reference current signal. Also part of this embodiment is a feedback path configured to provide the modulation current control signal and the bias current control signal to a driver to control the modulation current and bias current that the driver uses to drive an optic signal generator.

In one embodiment, the reference signal is the data signal or a duplicate of the data signal. The monitor photodiode signal detects an optic signal generated by an optic signal generator based on a data signal transmitted into an optic fiber such that the optic signal representing the data signal. For example, the monitor photodiode signal may be formed from a representation of the data signal and error introduced by the monitor photodiode.

In one configuration, the modulation control path includes, in any order, a transimpedance amplifier, one or more filters, a single ended to differential signal format conversion module, a mixer, and a comparator. In one embodiment, the bias control path includes, in any order, a transimpedance amplifier, one or more filters, an average weighting module and a comparator. The feedback path may comprise a comparator and digital to analog converter. It is contemplated that a first feedback path is associated with the modulation control path and a second feedback path is associated with the bias control path. In one configuration, the modulation control path calculates a power value of the monitor photodiode signal and the reference signal and the bias control path calculates an average power level of the monitor photodiode signal and the reference signal.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### 5. BRIEF DESCRIPTION OF THE DRAWINGS

The components in the figures are not necessarily to scale, emphasis instead being placed upon illustrating the principles of the invention. In the figures, like reference numerals designate corresponding parts throughout the different views.

FIG. 1 illustrates an exemplary optic fiber communication link.

FIG. 2A shows current variation over temperature for a laser.

FIG. 2B shows laser slope efficiency variation over temperature for the same laser.

FIGS. 3A and 3B, are plots of the optical power level of the transmitted signal.

A typical closed loop power control system is shown in FIG. 4A.

FIG. 4B is a plot of the monitor photodiode output over time.

FIG. 5A illustrates a block diagram of an example optical signal transmit system and exemplary environment of use for the dual closed loop control system.

FIG. 5B illustrates an exemplary block diagram of the dual closed loop architecture in accordance with one embodiment of the innovation described herein.

FIGS. 6A and 6B illustrate the signal filter output waveform in the transient domain in relation to the monitor photodiode output.

FIG. 7A illustrates a signal plot of the ideal MPD signal

FIG. 7B illustrates a signal plot showing an error ˜ΔIM in the modulation current.

FIG. 7C illustrates a signal plot showing an error ˜ΔIB in the bias current.

FIG. 7D illustrates a signal plot of the ideal MPD signal with weighted averaging

FIG. 7E illustrates a signal plot showing an error ˜ΔIM in the modulation current with weighted averaging.

FIG. 7F illustrates a signal plot showing an error ˜ΔIB in the bias current with weighted averaging.

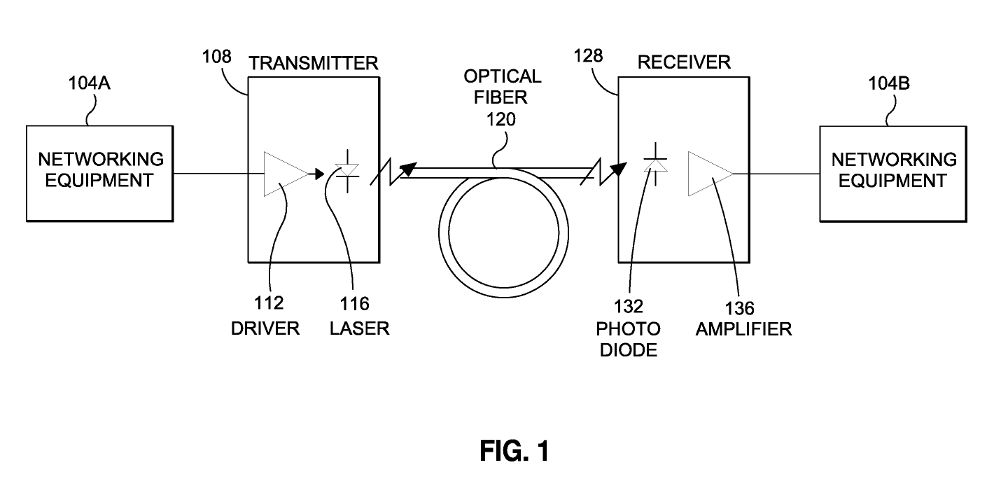

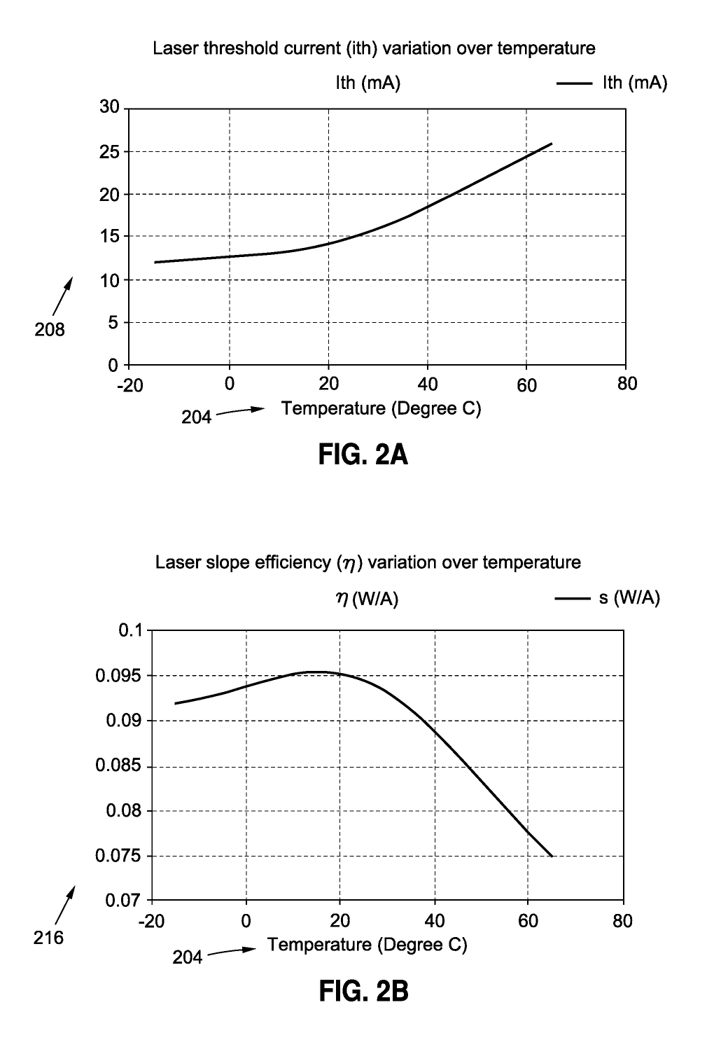

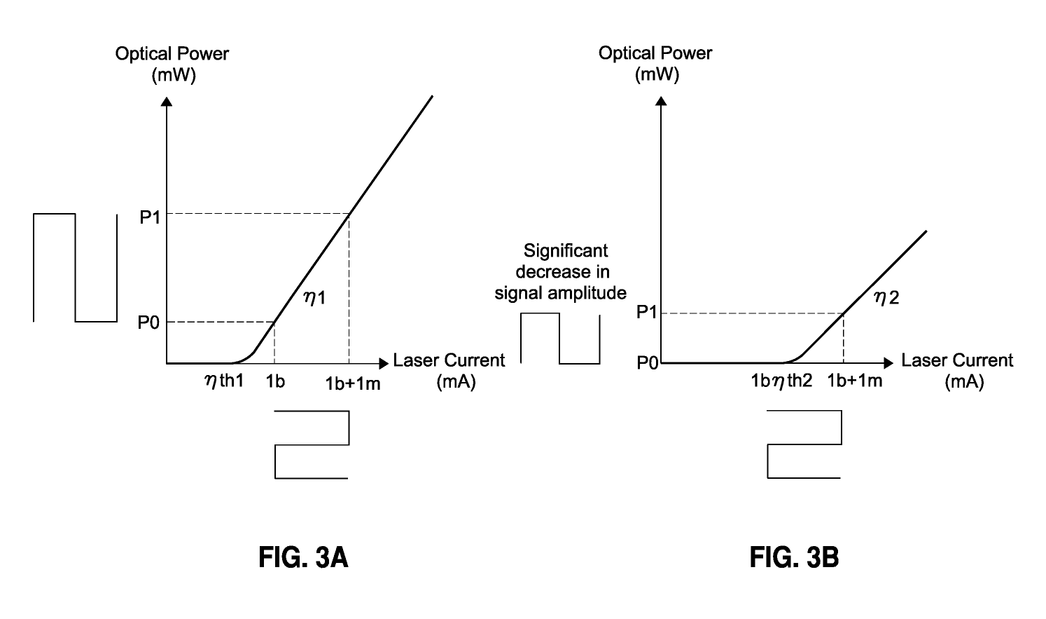

### 6. DETAILED DESCRIPTION

The following are the different methods for controlling the transmit power of laser: Open loop (OL) control, Single closed loop (SCL) control, Optical amplitude modulation (OMA), and Dual closed loop (DCL) control. Each is discussed below in relation to the innovation disclosed herein.

### Open Loop Control

In open loop control, the values of bias and modulation currents are measured for desired Pavg and ER for a laser over temperature. These values are noted and stored in a look up table (LUT). LUT data is stored in a memory (EEPROM) which may be off chip or integrated with laser driver. The change in laser temperature is detected by a temperature monitor. Based on the detected temperature, the laser driver downloads the bias and modulation current configuration from an EEPROM. This method does not require a monitor photodiode (MPD) for monitoring laser power. EEPROMs are significantly more expensive than MPDs, which is another drawback to designs that require EEPROMS.

While the open loop control system has the advantage of being simple, it does suffer from several disadvantages. These disadvantages include that the LUT has to be created over temperature before being deployed in a real application or system. This takes time and eventually drives the cost up. In addition, an EEPROM is required which also increases cost.

A further disadvantage is that the lasers are characterized for a few discrete temperature levels which hurts accuracy in intermediate levels between levels. In addition, this open loop control method does not address laser parameter changes due to aging.

### Single Closed Loop Control

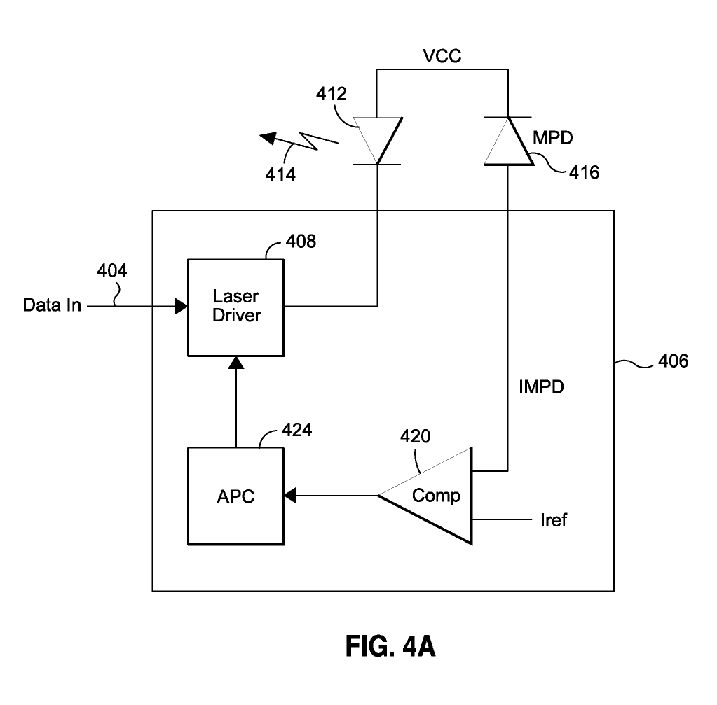

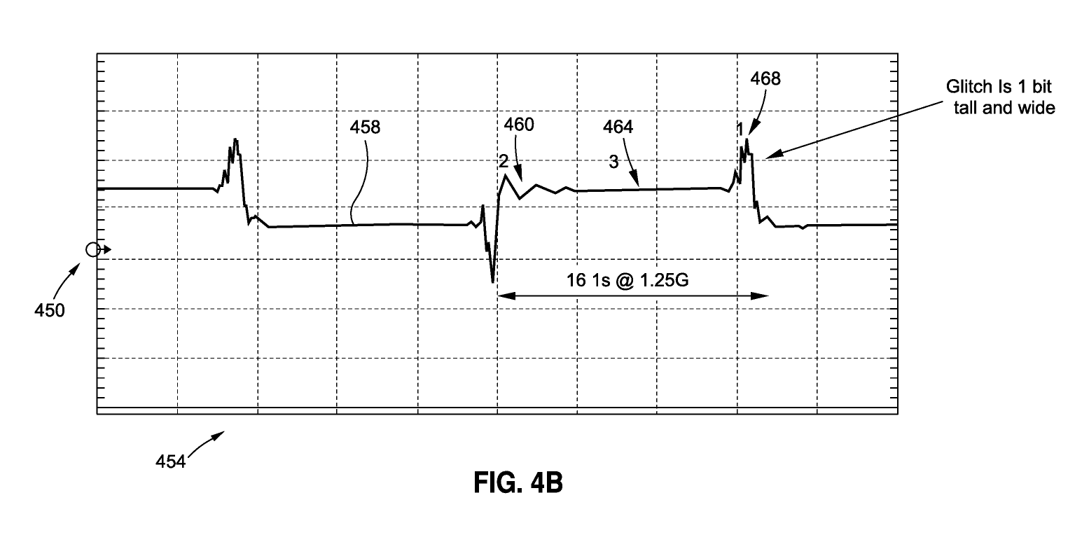

The most common closed loop control is single closed loop (SCL). This method requires an MPD (which may be attached or integrated with laser) which produces a current proportional to the laser output power. This current represents the power transmitted by laser. In SCL, this detected average power is compared with a reference average power. The loop is closed by controlling bias or modulation current based on the comparison result. In this way, the fixed average power is maintained over temperature or aging of the laser. The concept is shown in FIG. 4 (discussed above), where IMPD can be thought of average MPD current.

There are several advantages to SCL such as that the LUT must be created only for bias or modulation current, while the other current is controlled by the loop. Further, the SCL implementation is simple. However, several disadvantages of SCL are present including that either the bias or modulation current must still be characterized for each laser, which is time consuming and costly. In addition, SCL requires an EEPROM to store the LUT for the one or more of currents and a large ER variation is possible. Large ER variation is undesirable.

### Optical Amplitude Modulation

Another common way to control both modulation and bias currents is known as Optical Modulation Amplitude (OMA). In this method, Pavg of the optical output from the laser is detected and controlled by a bias current. An initial value is used for modulation current. This is similar to SCL operation. Once the Pavg is stable, the reference average power Pref is varied by a very small amount, namely by an amount ΔPref, which results in a small change in bias current, ΔIb (delta indicating change). Calculation of slope efficiency occurs using following equation (3).

$$1. η = \frac{Δ Pref}{Δ Ib} \qquad ( 3 )$$

In actual implementation, the slope efficiency may or may not be directly calculated. Usually the modulation current is calculated next based on the change in bias current and initial modulation current.

There are several advantages to OMA, such as use of a LUT or EEPROM is avoided. In addition, a simple analog front end for average power detection may be used. Moreover, a low speed MPD is sufficient. There are several disadvantages to use of OMA though, such as that OMA is limited to small ER targets (<10 dB) and it requires a complicated digital implementation.

### Dual Closed Loop

The main motivation for dual closed loop (DCL) is to eliminate the need for the LUT which saves time and does not require an EEPROM, which results in much lower implementation cost. In DCL, both the bias and modulation currents are controlled by the loop, and thus the name is dual closed loop.

There are various ways to implement DCL. The most common way is with peak detection. In this method, both of the P1 and P0 peaks from the MPD current are detected separately. P0 peak is compared with a reference P0 level and used to control the bias current. Similarly, P1 peak is compared with a reference P1 level and used to control the modulation current.

Traditional DCL control has several advantages. For example, it eliminates the need for the LUT i.e. shorter test time and lower cost, and it eliminates the need for an EEPROM resulting in a lower cost. In addition, DCL control is more stable ER and Pavg over temperature and aging. Traditional DCL control does have several disadvantages though. First, it requires an accurate high speed MPD which drives the cost up, and it will use substantially more power than other architectures.

### Next Generation Dual Closed Loop

One drawback to the prior art systems is that none of the prior art systems addressed the signal anomalies, such as glitches and settling time associated with the monitor photodiode output. FIG. 4B is a plot of the monitor photodiode output over time. The vertical axis 450 represents voltage (signal magnitude) while the horizontal axis 454 represents time. The signal 458 is the monitor photodiode output transitions to high and low values in response to the transition of the laser that generates the optic signal. This signal 458 suffers from several anomalies. For example, at signal portion 460, the signal suffers from ringing. At signal position 464 the signal, which generally settled to steady state, suffers from small fluxions or noise. At signal position 468 the signal includes overshoot as the signal transitions states. All of these anomalies may be characterized as glitches. These can be intrinsic to the MPD behavior of be caused by other impairments in the system such as coupling, noise, interference, etc.

These glitches became larger in magnitude as the industry moves to lower cost optical subassembly technology. As a result, peak detection on this signal from the monitor photodiode is unsuitable for automatic power control of laser.

Following are the issues that next generation dual closed loop architecture as proposed herein solves. These issues were directly or indirectly created by MPD glitches.

1. Low maximum Extinction Ratio (ER)

2. ER variation over temperature

3. ER variation over pattern

4. ER variation due to pattern inversion

5. Large number of steps for ER calibration ˜ Longer test time

6. Architecture is too complicated to understand, etc.

In addition, the next generation dual closed loop as disclosed herein is also suitable for lower cost CMOS or BiCMOS technology due to its low speed nature. Since the previous architecture employs peak detection it requires higher speed technologies which eventually would drive the cost up. Moreover, the new architecture can be implemented to dissipate only half the power of the previous architecture primarily due to the low speed nature.

To overcome the drawbacks of the prior art, disclosed is a closed loop power control method and apparatus for an optic signal generator, such as a laser in a communication system. The following is a description of one example embodiment. It is contemplated that other embodiments may be arrived at without departing from the scope of the claims.

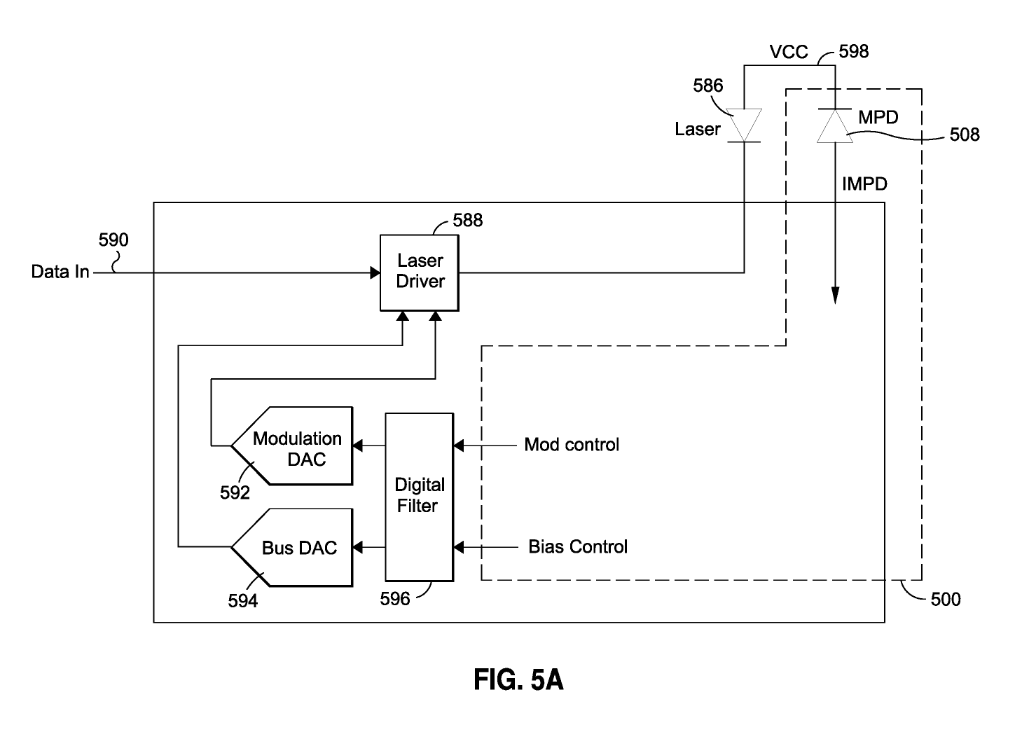

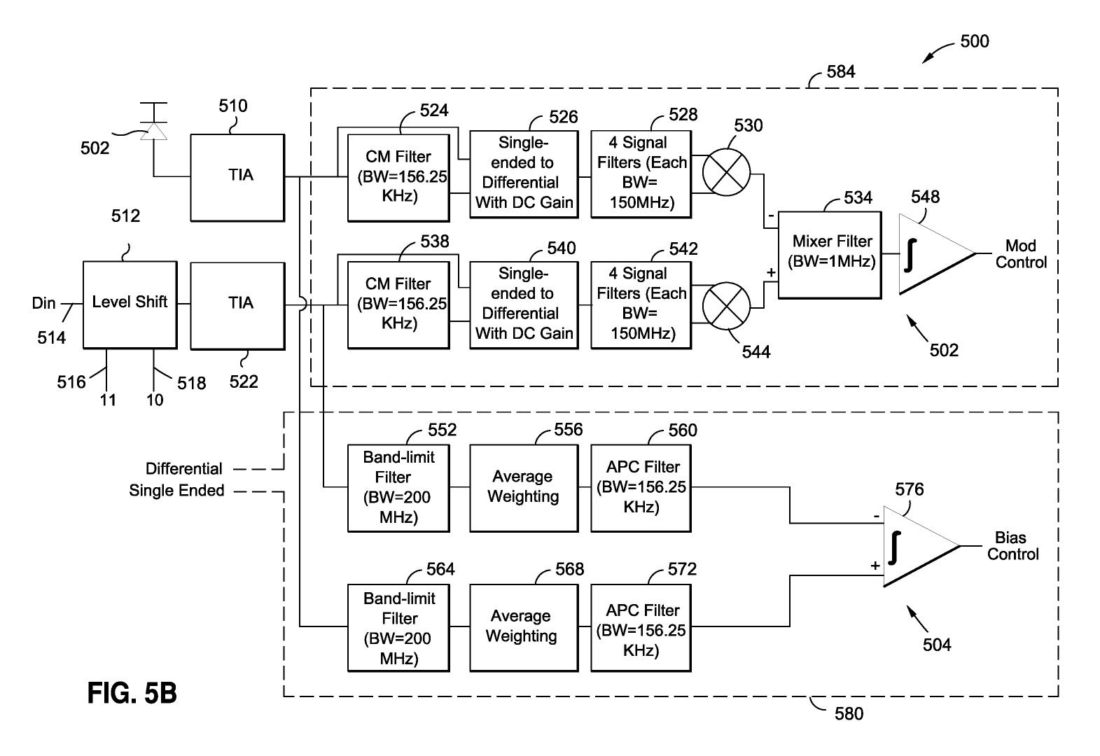

FIG. 5A illustrates a block diagram of an example optical signal transmit system and exemplary environment of use for the dual closed loop control system. This is but one example embodiment and it is contemplated that other configurations may be enabled based on the description that follows. In this system, a data input 590 provides data to be optically transmitted to a laser driver 588. The laser driver 588 also receives a modulation control signal from a modulation DAC 592 and bias control signal from bias DAC 594.

The laser driver modulates and biases the data signal to levels suitable for driving the laser 586 and provides the data signal to the laser for generation of an optic signal. The laser 586 and MPD 508 are biased with a voltage Vcc on node 598. Common anode MPD and common cathode laser implementation are also contemplated as possible design options and such design options would not depart from the claims that follow.

One or more digital filters 596, configured in this embodiment as counters, provide input to the modulation DAC 592 and the bias DAC 594. The digital filter 596 controls the rate of change of the modulation control loop and the bias control loop.

The control loop block 500 receives the MPD 508 input. The MPD 508 may be part of the control loop block 500 or considered a separate element. The MPD 508 is shown in FIG. 5A and FIG. 5B to provide relationship between the block 500 and the system of FIGS. 5A, 5B. The control loop block 500 is shown and described in detail in FIG. 5B.

In operation, as data is transmitted by the laser 584, the MPD 508 provides a feedback signal to the control loop block 500. The control loop block 500 processes the feedback signal, which contains unwanted glitches, in a manner that is more accurate than the prior art, to generate a modulation loop control signal and a bias loop control signal, both of which are provided to the digital filter 596. The digital filter (FIG. 5A) controls the speed of the control loop.

The digital filter 596, the modulation DAC 592, and the bias DAC 594 utilize the control signals to adjust the modulation current and bias current for the laser driver 588 to accurately account for changes in the laser that occur over time and temperature and which were not accurately adjusted in the prior art due to the less than ideal signal from the MPD 508.

FIG. 5B illustrates an exemplary block diagram of the dual closed loop architecture 500 in accordance with one embodiment of the innovation described herein. In general, the feedback loop that controls bias current is called Automatic Power Control (APC) loop 504 and the feedback loop that controls modulation current is called Modulation Current Control (MCC) loop 502. Each element is discussed below.

As shown, a photodiode 508 monitors an optic signal by an optic signal generator to create an electrical signal representing the actual transmitted optical signal. The electrical output of the photodiode 508 connects to a transimpedance amplifier (TIA) 510.

The TIA 510 converts the current from the photodiode 508 to a voltage. The output of the TIA 510 is provided as an input to a CM (common mode) filter 524 and to a single ended to differential format module 526, and to a band limited filter 564. The path (APC loop) which includes the band limit filter 564 is discussed below. The common mode (CM) filter 524 is configured to convert the single ended output from the TIA 510 to a differential format signal suitable for use by a mixer. The CM filter 524 converts the signal from the TIA to a differential signal as well as the filtering of the signal which is optional. The single ended to differential format module 526 also receives the output from the CM filter 524. The signal ended to differential format module 526 converts the single ended signals to a differential signal.

The output of the signal ended to differential format module 526 connects to a filter 528. In this embodiment, the filters 528 comprise four filters each of which have a bandwidth of ˜ 150 MHz. In other embodiments, more or fewer filters 528 may be used and the bandwidth of each filter may be different than 150 MHz.

The outputs from the filters 528, 542 connect to a mixer 530. The mixer 530 is configured to determine the power of the signal, such as by squaring the input signal. The output of the mixer 530 serves as an input to the mixer filter 534.

Returning now to the TIA 510, which provides an input to the band-limit filter 564. The band limit filter 564 is configured for use with and to assist with averaging weighting as described herein. It is beneficial to have a filter before the averaging weighting module. In addition, the glitches in the monitor photodiode are not symmetric and, as a result, the averaging process may yield incorrect results without the band limit filters 564, which results in a more accurate signal power average. The output of the band-limit filter 564 connects to an average weighting module 568. The average weighting module 568 is configured to skew or adjust the bias control to prevent an error in the modulation loop from affecting the bias control loop. As way of discussion, in the disclosed system there are two outputs, namely the modulation control signal and the bias control signal, both of which determine, such as by current control, one or more aspects of laser operation. Each loop is somewhat independent and the modulation control signal and loop is based on signal power. However, an error in the modulation control loop may propagate to the bias control loop which is less independent. Any error in the modulation control loop can thus jump to bias control loop. The averaging weighting skews the bias control signal to cause to create an ‘offset’ in the loop so that it become less dependent on the modulation control loop, and thus an error is not created in the bias control signal due to the modulation control loop operation.

The output of the average weighting filter 568 is provided to an automatic power control (APC) filter 572, which in this embodiment has a bandwidth of 156.25 kHz. The APC (average power control) filter 572 is configured to produce and average of the input signal. While the mixer in the modulation control loop calculates the power of the signal, the APC filter calculates the average of the signal to control bias control current. The output of the APC filter 572 connects to a comparator 576. The comparator 576 is discussed below in greater detail.

Also shown in FIG. 5A is a current switcher module 512 that receives inputs Din 514, input I1 516 and inputs I0 518. The current switcher module 512 is configured to generate a reference current signal. In the embodiment of FIG. 5A, the input Din 514 is a voltage signal that has a logic level or voltage level that corresponds to the data signal to be transmitted, such as for example a one or zero. The current switcher module 512 generates a corresponding current signal. When the value of Din is one, then I1 current is output and when the input Din is logic zero, then the current output is I0. The current output from the current switcher module 512 is used to mirror, with a reference signal, the MPD 508 output, which is a current. The input Din 514 comprises a voltage signal that is at the same logic level as the data being transmitted. The input I1 is a current corresponding to a high logic level input while the input I0 is a current corresponding to a low logic level input. The output of the current switcher module 5123 connects to a TIA 522. The TIA 522 converts the current switcher module output to a voltage suitable for input to a CM filter 538 and a band limit filter 564. The signal path through the CM filter 538, a single ended to differential format module 540, and filters 542 is generally similar to the elements 524, 526, 528 as described above and are not described in detail again. The output of the filters 542 connects to a mixer 544, which is generally similar to the mixer 530. The output of the mixer 544 connects to the mixer filter 534. The mixer filter 534 is configured to square the input signal to generate a power signal. The output of the mixer changes over time and the intent is to determine the average power. The output of the mixer filter 534 connects to the comparator 548.

The output of TIA 522 also connects to a band-limit filter 552. The band-limit filter 552, average weighting module 556, and APC filter 560 are generally similar to elements 564, 568, 572 described above and are not described in detail again. The output of the APC filter 560 connects to the comparator 576.

The comparator 548 is configured to receive and compare two inputs, in differential mode, namely the P and N terms of the differential signal are compared. The resulting output of the comparator 548 is a modulation control current which is fed back into the digital filter 596 (FIG. 5A) to control the modulation current to adjust or account for changes in laser operation over temperature and aging.

The comparator 576 is configured to compare the two inputs and generate an output (typically a logic level high or low signal) based on the comparison. The resulting output of the comparator 576 is a bias control signal which is fed back into the digital filter 596 (FIG. 5A) to control the bias current or other aspect of the bias signal to adjust or account for changes in laser operation over temperature and aging.

The various filters referenced herein may comprise any type filter including but not limited to passive RC filters or any other type of filter whether passive or active filters.

In operation, the APC loop 580, the average photodiode 508 current is calculated by filtering the monitor TIA output with an RC filter, such as filters 552, 564, 560, 572. Since this is averaging also includes the unwanted glitches in monitor photodiode 508 current, the averaging has minimal effect, assuming glitches are symmetric on both P1 and P0 levels, which is true in most of the cases. A lower bandwidth for the loop is preferred for better filtering but higher bandwidth is preferred for quick settling burst mode operation. During operation, the average value is compared with average target value from the current switcher module 512, which serves as a reference value. If the comparator 576 output is high, the bias current is increased but if the comparator output is low, the bias current is decreased. This APC loop 580 also incorporates average weighting 556, 568 and offset cancellation which is discussed below.

For the modulation current control (MCC) loop 584, the focus is to filter the MCC loop 584 current, but not as much as in APC loop 580, where filtering is higher, to create the average signal. In the MCC loop 584, the filtering is performed to an extent so that a desired amount of signal amplitude is still present for subsequent downstream processing. As discussed below, if the signal amplitude is too high, then insufficient filtering may have occurred and the glitch is not removed or addressed. If the signal amplitude is too low, then the signal amplitude may not be suitable for processing by subsequent stages. In this way, the glitches are filtered more than the signal itself thereby yielding the desired output with the glitch removed or reduced. As a result, the signal to glitch power ratio increases which more accurately detects signal level. In this embodiment, a lower cutoff frequency for the four signal filters 528, 542 results in a higher signal to glitch ratio, and vice versa. However, if too low of a cutoff frequency is selected for the four signal filters 528, 542, the very low signal amplitude at the output of signal filter which may be difficult to be resolved by the subsequent stages.

In the embodiment described herein, instead of using one (single) stage filtering, four stage filtering 528, 542 are used to establish 80 dB/decade slope for high frequency cutoff roll off. The four signal filters 528, 542 remove the unwanted glitch. In other embodiments, a great number of a fewer number of filter stages may be used. In this embodiment, the signal filter stages have identical cutoff frequencies, but in other embodiment, the filters 528, 542 may be configured with differing cutoff frequencies. For example, with default register setting each filter stage 528, 542 has 150 MHz of cutoff frequency. With four filter stages in series the overall cutoff frequency is 66 MHz. This ensures minimum output voltage of 240 mV. In general, the cut off frequencies of the filters and their cut off frequency can be chosen by someone skilled in the art by analisyng the impairments of the MPD filter.

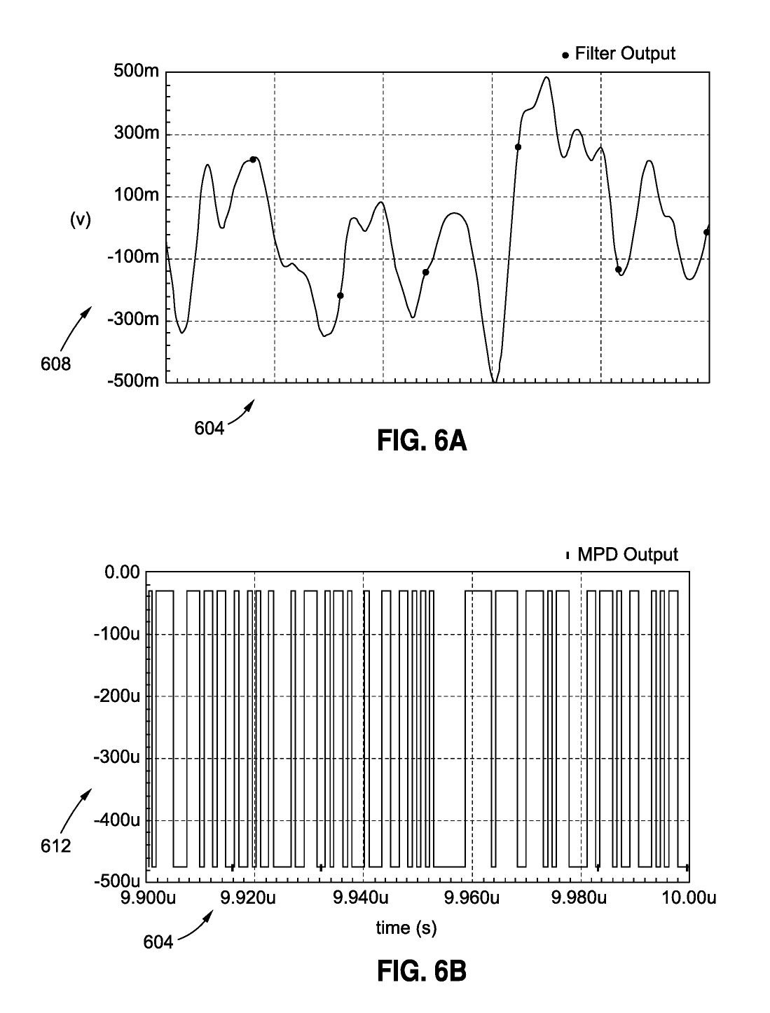

The following waveforms shown in FIGS. 6A, and 6B illustrates the signal filter output waveform in the transient domain in relation to the monitor photodiode output. In FIG. 6A, the horizontal axis 604 represents time while the vertical axis represents voltage. This illustrates the filter output over time. In FIG. 6B the horizontal axis 604 represents time while the vertical axis represents current. This illustrates the monitor photodiode 508 output over time.

The output of the signal filter 528, 542 is squared using a mixer 530, 544. As a result, the output of the mixer 530, 544 is proportional to the power of the output of the signal filter 528, 542. This method of power detection also provides more tolerance to the monitor photodiode 508 glitches than other processes like peak detection.

The output of the mixer 530 is compared with a reference voltage from mixer 544. If the comparator 548 output is high, the modulation current is increased while if the comparator output is low, the modulation current is decreased. The mixer output 530, 544 is filtered by the mixer filter 534 to extract the low frequency value from the signal before it is sent to MCC loop 584 comparator 548. In one embodiment, a high cutoff frequency for the mixer filter 534 is chosen to support burst mode. Since the output of both the APC comparator 576 and MCC comparator 548 is decimated in a digital filter, low analog cutoff frequencies are avoided to speed up the burst operation.

In this example embodiment, the reference voltage for the MCC loop 584 should not be a fixed DC voltage proportional to target currents. Since the main signal goes through filtering and mixing (squaring), the target currents also need to go through a replica TIA 522, signal filter 538 542, and mixer 544 before they could be used as a reference. As a result, the reference signal from the current switcher module 512 going into the TIA 522 is preferably a transient signal switching between IP1_target 516 and IP0_target 518. Since access is available to the data signal that was transmitted, a replica data current signal is created that switches between IP1_target 516 and IP0_target 518. The block that generates this current switching waveform is called current switcher 512

The inputs to the mixers 530, 544 are from the outputs from the filters 528, 542 and are preferably in differential signal format for the mixer architecture. In other embodiments, other arrangements are possible. However, in this embodiment, the TIA 522, 510 output is single ended. To create a differential signal from a single ended signal, the average of the single ended signal is subtracted out from the single ended signal itself in the single ended to differential signal format module 526, 540. This creates a high pass function with the cutoff frequency of the average filters (APC filters 560, 572). This average filter 556, 568 is the same average filter which generates the average for APC loop 580. If the average filter 556, 568 cutoff frequency is adjusted or changed, such change would also change the low cut off frequency of the signal filter path.

The TIA 510, 522 output and average filter 556, 568 outputs are fed to first stage of signal filter. This stage acts as the differential to single ended converter 526, 540.

Returning to the MCC loop 584, in one embodiment, the output of the mixer 530, 544 is large enough to be resolved by the comparator 548. In addition, it is contemplated that the input to the mixer 530, 544 should be large enough to meet specification for other components. As a result, the signal filter stages also work as gain stages between monitor TIA and mixer. The typical total DC gain of these stages is 2.5-3× but in other embodiments other values may be used. However, this gain varies substantially over PVT. In some cases, the gain is too small, so the output amplitude is likewise too small.

In some cases, gain setting may be too large which results in a loss or degradation in linearity. As a result, gain regulation is established. The gain may be controlled in any manner known in the art or developed in the future. However, this gain regulation is preferably not established using live data because these signals are part of the modulation current loop. As a result, gain regulation is done via gain calibration. During gain calibration, the TIA 510 is disconnected from monitor photodiode 508. A known low frequency (˜12.5 MHz clock) signal is provided to the input of a TIA 522. This known low frequency signal (which may be referred to a reference signal) is in or near the middle of the signal filter 428, 542 frequency band so that the peak of the signal output can be reliably detected. The peak is detected and it is compared with fixed reference. MCC loop comparator 534 is used for this comparison. During gain calibration loop filter is maintained without change. In various embodiments, gain calibration can be enabled only on power up, periodically, or continuously. Offset calibration and gain calibration are used in this design and both are standard and as such are not described in detail. Gain calibration helpful for this loop because the input to the mixer requires a high voltage and using of gain calibration makes sure the signal output level is large enough. The calibration may be done offline, when the system is not processing data. Thus, calibration may be performed periodically.

The signal filters 528, 542 have a DC offset at the output. In the embodiment described herein, the offset is removed by using a DC offset correction loop, between or part of the signal filters 528, 542 and the mixers 530, 544. This loop may have a very slow time constant, so it is preferably not used for burst mode applications. It is recommended to shut this loop down for burst mode applications. In addition, this offset is not that significant compared with the signal amplitude at the output of the filter.

The outputs of two comparators 548, 576 are sent to a digital counter (not shown). The digital counter samples the output of the comparator 548, 576 with a clock. The counters update the codes that are provided to a bias DAC (not shown) and a modulation DAC (not shown) after one decimation cycle. If the decimation cycle is 64, the counter samples the comparator 548, 576 output 64 times. If the number of 1s is is greater than the number of 0s then the code to DAC goes up by 1 count after decimation cycle and vice versa. If the decimation is too high, the update rate will be very slow. If decimation is too low, the comparator output might be still settling and the samples will not be valid. If this occurs, the loop may converge at the wrong location and may even oscillate. The output of the DACs bias DAC (not shown) and a modulation DAC (not shown) provide the control input to the digital filter 596.

### Weighted Averaging

Weighted averaging may be available in dual closed loop (hereafter DCL). In DCL, the APC loop 580 changes the bias current based on the average current from the monitor photodiode 508. The average of the monitor photodiode 508 current is proportional to average laser power, which is in turn proportional to (Im+2*Ib−2*Ith)/2 where Im is modulation current, Ib is bias current, and Ith is threshold current. In this embodiment, the modulation current Im is set by the MCC loop 584.

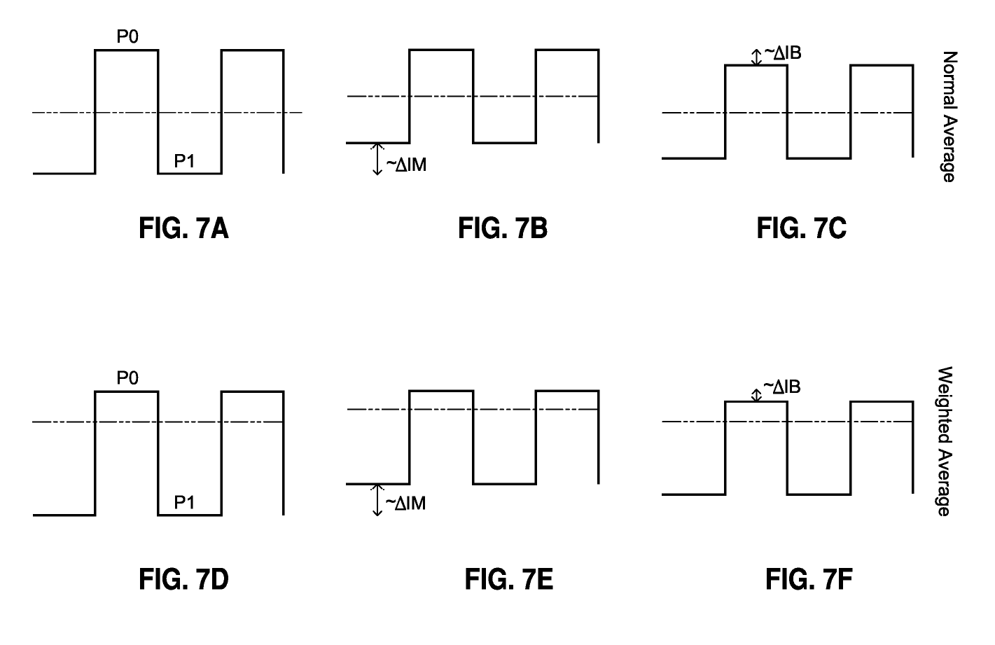

FIG. 7A illustrates a signal plot of the ideal MPD signal. FIG. 7B illustrates a signal plot showing an error ˜ΔIM in the modulation current. FIG. 7C illustrates a signal plot showing an error ˜ΔIB in the bias current.

The signal from the monitor photodiode is shown in FIG. 7A. If there is an error in the MCC loop 584 due to a glitch in monitor photodiode 508 current waveform (FIG. 7A), then as shown in FIG. 7B, current Im will be off by a certain amount (˜ΔIm). This means the average power will be in error by an amount proportional to ˜ΔIm, which is generally unwanted because the current control for the transmit laser will be adjusted in error due to the MCC loop 584. The APC loop 580 will detect this error and will correct the average power by shifting Ib by an amount ΔIb=ΔIm/2 as shown in FIG. 7C. Note that the location of P1 and P0 are reversed as these waveforms are considered as TIA 510 output where the monitor photodiode 508 signal is inverted with respect to ground.

Usually the change in Im, due to the monitor photodiode 508 glitch is negative, which in turn cause the change in Ib to be positive. This results in a lower P1 value and higher P0 levels at the laser output, which causes a lower extinction ration (ER) than the target ER which is not desired.

In order to overcome this drawback, a weighted average instead of absolute average is proposed herein. FIG. 7D illustrates a signal plot of the ideal MPD signal with weighted averaging. FIG. 7E illustrates a signal plot showing an error ˜ΔIM in the modulation current with weighted averaging. FIG. 7F illustrates a signal plot showing an error ˜ΔIB in the bias current with weighted averaging.

In absolute average, the average value is essentially in the middle of the signal (P1+P0)/2. In weighted average, the average value could be skewed toward P1 or P0. In the waveform above, average is skewed toward P0. As a result and as shown in FIG. 7F, ΔIb (weighted) is smaller than ΔIb (unweighted). This results in less error in APC loop 580 or Ib and higher ER. However, in the presence of the glitch, skewing the average toward P1 produced more desired result (lower ΔIb).

The following equations set forth a mathematical representation of the weighted averaging calculations.

$$Pavg = \frac{{P}_{1} + {P}_{0}}{2} = \frac{η}{2} ( IM + 2 IB - 2 Ith ) = \frac{η}{2} ( IM - Δ IM + 2 IB + 2 Δ IB - 2 Ith )$$

$$Δ IB = Δ IM / 2$$

$$Pavg = \frac{x ( {P}_{1} - {P}_{0} ) + 2 {P}_{0}}{2} = \frac{η}{2} ( xIM + 2 IB - 2 Ith ) = \frac{η}{2} ( xIM - x Δ IM + 2 IB + 2 Δ IB - 2 Ith )$$

$$Δ IB = x Δ IM / 2$$

$$Pavg = \frac{x ( {P}_{1} + {P}_{g} - {P}_{0} ) + 2 {P}_{0} - {P}_{g}}{2} = \frac{η}{2} ( xIM + xIg + 2 IB - 2 Ith - Ig ) = \frac{η}{2} ( xIM + xIg - x Δ IM + 2 IB + 2 Δ IB - 2 Ith - Ig )$$

$$Δ IB = \frac{x Δ IM - ( x - 1 ) Ig}{2}$$

In these equations, the terms P1 and P0 are defined as the power levels, while Pavg is the average power. The variable IM is the modulation current and IB is the bias current. The variable Ith is the threshold current and the variable η is slope efficiency. The variable Ig is defined as glitch current amplitude.

Turning to the APC loop 580, the TIA 510, 522 output is filtered with band limit filter (BLF) 552, 564 before it is sent to weighted average module 556, 568. The filtering by the band limit filter (BLF) 552, 564 occurs to reduce the glitch. After weighting of the signal is performed, the signal is processed to be averaged again by the APC filters 560, 572 before it is sent to APC comparator 576. In this embodiment, prior art technics are not effective as it is used in the MCC loop to extract the common mode of TIA signal. Therefore, a separate weighted averaging filter 556, 568 is utilized in the APC loop 580. In this embodiment, the weighted averaging filter 556, 568 has the same cutoff frequency as the other averaging filters 556, 568, but in other embodiments, a different cutoff frequency may be used. A higher pole frequency of the filter 556, 568 is recommended for burst mode operations.

### Peak Detection Mode

To achieve peak detection in the default mode, the signal filters 528, 542 output is squared using mixer and then used for modulation current control. In peak detection mode, instead of using the mixer output, the output of the signal filter is peak detected and used for modulation current control. The peak of the signal filter is used for peak detection rather than peak of monitor TIA as in classical peak detection for automatic power control. This mode was available by using the existing peak detectors in either, or both, of the main and replica signal paths for gain calibration.

The peak detection mode should be treated as an alternative to the mixer mode as described above. In some embodiment, peak detection mode is less desirable due to susceptibility to glitch magnitude detection in the peak detection process which results in an inaccurate peak detection. By detecting squared signal (˜power) in mixer mode, the loop is less sensitive to glitches on monitor photodiode 508.

### Burst Mode Considerations

In burst mode, the laser output can be enabled or disabled based on a burst enable signal (BEN). The burst enable signal (BEN) typically is from a pin on a package that is configured to provide the burst control signal. This signal could be a CMOS rail to rail single ended signal or a differential signal. If the BEN is logic high, the laser output is enabled. If the BEN is logic low, the laser output is disabled. The following table set forth maximum and minimum burst on and off time based on typical GPON application in one example embodiment.

| Condition | Minimum | Maximum |
|---|---|---|
| Burst on | 100 ns | 125 μs |
| Burst off | 25.6 ns | ∞ |

This disclosure is applicable to other time division multiplexing systems with different burst-on/off time through the proper selection of system clock and signal filtering bands.

Once the laser is disabled during burst off, the monitor photodiode 508 output will also be disabled. During that time, the automatic laser power control loop can be configured to ignore the monitor photodiode 508 output and be frozen or disabled. In one embodiment, this is done by freezing or disabling the digital filter. Also during this time monitor photodiode 508 is disconnected from the monitor TIA 510. The input of monitor TIA 510 is connected to a replica signal, such as the output from the current switcher 512. As a result, the analog filter voltages are preserved during burst off time. If this does not occur, then the filter voltages may drift by substantial amount during burst off time. So when the device comes back into burst on phase (mode), the filters would take a long time to settle within an acceptable amount of error. By keeping the filter voltages preserved during burst off this problem is avoided.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

While various embodiments of the invention have been described, it will be apparent to those of ordinary skill in the art that many more embodiments and implementations are possible that are within the scope of this invention. In addition, the various features, elements, and embodiments described herein may be claimed or combined in any combination or arrangement.

1. An optic signal generator power control system comprising:
a laser driver configured to receive and process a data signal, a modulation control signal, and a bias control signal, and process, responsive to the modulation control signal, and a bias control signal, the data signal to drive an optic signal generator for generation of an optic signal that represents the data signal;
a monitor photodiode configured to receive the optic signal and generate a monitor photodiode signal, the monitor photodiode signal comprising the data signal and errors introduced by the monitor photodiode or other system impairments;
a modulation control path configured to process the monitor photodiode signal, the modulation control path including at least one filter and average weighting module configured to remove errors in the monitor photodiode signal;
a bias control path configured to process the monitor photodiode signal, the bias control path including at least one filter and at least one mixer configured to remove errors in the monitor photodiode signal;
one or more counters configured to receive the output of the modulation control path and the bias control path and responsive thereto, generate one or more digital output signal;
modulation digital to analog converter configured to convert the digital output signal from at least one of the one or more counters to the modulation control signal;
bias digital to analog converter configured to convert the digital output from at least one of the one or more counters to the modulation control signal.

2. The system of claim 1, wherein the error in the monitor photodiode consists of one or more of the following: overshoot, ringing, and noise.

3. The system of claim 1, wherein the modulation control path includes a comparator configured to compare a processed version of the monitor photodiode signal to a reference signal, the reference signal undergoing the same processing as the monitor photodiode signal in the modulation control path.

4. The system of claim 1, wherein the bias control path includes a comparator configured to compare a processed version of the monitor photodiode signal to a reference signal, the reference signal undergoing the same processing as the monitor photodiode signal in the bias control path.

5. The system of claim 1, wherein the modulation control path includes a transimpedance amplifier, a common mode filter, a single ended to differential format module, one or more signal filters, a mixer, a mixer filter, and a comparator.

6. The system of claim 1, wherein the bias control path includes band-limit filter, an average weighting module, an average power control filter, and a comparator.

7. An optic signal generator power control system comprising:
a laser driver configured to receive a data signal, and responsive to a modulation control signal, and a bias control signal, process the data signal to a format suitable for driving an optic signal generator to generate an optic signal that represents the data signal;
a monitor photodiode configured to receive the optic signal and generate a monitor photodiode signal, the monitor photodiode signal comprising the data signal and errors introduced by the monitor photodiode;
a modulation control path configured to process a monitor photodiode signal and a reference signal, both the monitor photodiode signal and the reference signal processed by at least one filter and at least one mixer that are in the modulation control path, the processing generating a modulation control signal; and,
a bias control path configured to process the monitor photodiode signal and the reference signal, both the monitor photodiode signal and the reference signal processed by at least one filter and at least one average weighting module that are in the bias control path, the processing generating a modulation control signal, wherein the bias control path and the modulation control path reduce or eliminate an effect of the error in the monitor photodiode signal.

8. The system of claim 7, further comprising a first transimpedance amplifier configured to process the monitor photodiode signal and a second transimpedance amplifier configured to process the reference signal.

9. The system of claim 7, further comprising:
one or more counters configured to receive an output of the modulation control path and an output of the bias control path and responsive thereto, generate one or more digital output signal;
modulation digital to analog converter configured to convert the digital output signal from at least one of the one or more counters to the modulation control signal; and
bias digital to analog converter configured to convert the digital output from at least one of the one or more counters to the bias control signal.

10. The system of claim 7, wherein the at least one filter in the modulation control path includes four signal filters and a mixer filter, and the at least one mixer in the modulation control path includes a mixer configured to calculate the power of the monitor photodiode signal and a mixer configured to calculate the power of the reference signal.

11. The system of claim 7, wherein the bias control path includes band-limit filter, an average weighting module, an average power control filter, and a comparator.

12. The system of claim 7, wherein the same processing is performed on the monitor photodiode signal and the reference signal.

13. A method for processing a monitor photodiode signal to remove errors in the monitor photodiode signal as compared to a corresponding data signal, the method comprising:
receiving the monitor photodiode signal;
receiving a reference signal;
processing the monitor photodiode signal and the reference signal with one or more transimpedance amplifiers to generate a monitor photodiode current signal and a reference current signal;
processing the monitor photodiode current signal and the reference current signal with a modulation control path to generate a modulation current control signal, the modulation control path including at least one mixer configured to generate the power of the monitor photodiode current signal and the power of the reference current signal;
processing the monitor photodiode current signal and the reference current signal with a bias control path to generate a bias current control signal, the bias control path including at least one average weighting module configured to determine an average value for the monitor photodiode current signal and the power of the reference current signal;
a feedback path configured to provide the modulation current control signal and the bias current control signal to a driver to control the modulation current and bias current that the driver uses to drive an optic signal generator.

14. The method of claim 13, wherein the reference signal is the data signal or a duplicate of the data signal.

15. The method of claim 13, wherein the monitor photodiode signal detects an optic signal generated by an optic signal generator based on a data signal transmitted into an optic fiber, the optic signal representing the data signal.

16. The method of claim 15, wherein the monitor photodiode signal is formed from a representation of the data signal and error introduced by the monitor photodiode.

17. The method of claim 13, wherein the modulation control path includes, in any order, a transimpedance amplifier, one or more filters, a single ended to differential signal format conversion module, a mixer, and a comparator.

18. The method of claim 13, wherein the bias control path includes, in any order, a transimpedance amplifier, one or more filters, an average weighting module and a comparator.

19. The method of claim 13, wherein the feedback path comprises a comparator, and digital to analog converter.

20. The method of claim 19, wherein a first feedback path is associated with the modulation control path and a second feedback path is associated with the bias control path.

21. The method of claim 13, wherein the modulation control path calculates a power value of the monitor photodiode signal and the reference signal and the bias control path calculates an average power level of the monitor photodiode signal and the reference signal.
